(19) United States
(12) Patent Application Publication
(10) Pub. No.: US 2009/0160472 A1
(43) Pub. Date: Jun. 25, 2009

(54) WAFER-LEVEL BURN-IN METHOD AND WAFER-LEVEL BURN-IN APPARATUS

(75) Inventors: Terutsugu Segawa, Osaka (JP); Minoru Sanada, Osaka (JP)

Correspondence Address: STEPTOE & JOHNSON LLP, 1330 CONNECTICUT AVE., NW, WASHINGTON, DC, 20036, US

(73) Assignee: MATSUSHITA ELECTRIC INDUSTRIAL CO., LTD, OSAKA (JP)

(21) Appl. No.: 12/064,093

(22) PCT Filed: Jun. 26, 2006
(86) PCT No.: PCT/JP2006/312701

§ 371 Date: Feb. 19, 2008

(30) Foreign Application Priority Data
Aug. 29, 2005 (JP) 2005-246905

(51) Int. Cl. G01R 31/02

(52) U.S. Cl. 324/760

(57) ABSTRACT

Temperature control in wafer-level burn-in is performed such that a set temperature used for the temperature control is corrected using a correction value calculated from the generated heat density of a wafer (101). Thus it is possible to eliminate a difference between the temperature of the wafer heated when an electrical load is applied and a control temperature for applying a thermal load, not depending on the distribution of good devices formed on the wafer (101) and the power consumption of the devices. As a result, the wear and burn of a probe can be prevented and highly reliable screening can be achieved.

### TECHNICAL FIELD

The present invention relates to a wafer-level burn-in method and a wafer-level burn-in apparatus which perform screening by applying an electrical load and a thermal load to a semiconductor wafer.

### BACKGROUND ART

Conventionally, in screening test apparatuses generally called burn-in apparatuses, defective pieces are screened by conducting power-on tests in thermal atmospheres at predetermined temperatures (e.g., 125° C.) to distinguish potential defects, after the packaging of IC chips having been obtained by dividing a semiconductor wafer.

Such a conventional apparatus requires a large thermostat and a large calorific value and thus has to be separated from other manufacturing lines. It has been desired to conduct burn-in tests on wafers before dividing the wafers into chips because wafers has to be transported, mounted in an apparatus, and loaded and unloaded into and from the apparatus, defective pieces found after packaging cause excessive packaging cost, and bare chips mounted without being packaged are demanded with assured quality.

In a burn-in apparatus responding to this demand, it is necessary to keep a semiconductor wafer at a constant temperature when applying a thermal load to the wafer. In order to respond to this demand, a wafer-level burn-in apparatus has been proposed which has the temperature regulating function of keeping a semiconductor wafer at a predetermined target temperature by means of heaters provided on both surfaces of the wafer.

Referring to FIG. 4, temperature control in conventional wafer-level burn-in will be described below.

FIG. 4 is a schematic diagram showing a conventional wafer-level burn-in apparatus. FIG. 5(a) shows a temperature distribution in the horizontal direction of a wafer when a thermal load is applied by the conventional wafer-level burn-in apparatus. FIG. 5(b) shows a temperature distribution in the vertical direction of the wafer when a thermal load is applied by the conventional wafer-level burn-in apparatus. FIG. 5 illustrates the temperature distributions in crossing directions on the wafer surfaces of chips.

In FIG. 4, a wafer 101 is held by a wafer holding tray 102 and is connected via a probe 103 to a substrate 104 to which an electrical load is applied. The probe 103 can collectively make contact with wafers. The electrical load is applied by a tester 105 having the function of applying an electrical load, generating electrical signals, and comparing the signals. A thermal load is applied by controlling a temperature regulating plate 106 to a set temperature such as 125° C. by heaters 108 disposed in the temperature regulating plate 106 and a coolant such as water and alcohol passed through coolant passages 107. The temperature of the temperature regulating plate 106 is controlled by controlling, from a temperature regulator 110, the calorific values of the heaters 108 and the temperature and flow rate of the coolant passing through the coolant passages 107, based on a temperature measured by a temperature sensor 109 that is in contact with the opposite side from the wafer holding side of the tray 102. In actual wafer-level burn-in, the temperature regulating plate 106 is heated by the heaters 108 from room temperature to the set temperature such as 125° C., an electrical load is applied to devices on a wafer by the tester 105, temperature control is performed by the temperature regulating plate, and the operations of the devices are confirmed at regular intervals by the tester 105 to check whether or not the devices formed on the wafer are failed, while keeping the set temperature. During the confirmation of operations, the electrical load applied by the tester 105 is interrupted and the devices are operated by applying, to the devices, an electrical signal for confirming operations. Then, outputs from the devices are monitored by the tester 105 to confirm whether or not the devices are failed by the electrical load and the thermal load.

In this configuration, the front side of the semiconductor wafer 101 has the devices formed thereon and is in contact with the probe 103, and the backside of the wafer 101 is held by the tray 102. Thus the temperature sensor 109 is brought into contact with the opposite side from the wafer holding side of the tray 102 and measures temperatures. Further, as IC chips decrease in size and an applied current increases, a calorific value per unit area increases when an electrical load is applied to a wafer. The increased calorific value per unit area increases a heat flux moved from the wafer by cooling for keeping a target temperature. Thus the temperature rapidly changes in the moving direction of heat and a difference between the actual temperature of the wafer 101 and a temperature measured by the temperature sensor 109 increases. Consequently, the temperature of the wafer deviates from a temperature for applying a thermal load.

As is evident from FIG. 5(a) showing the temperature distribution in the horizontal direction of the wafer when a thermal load is applied by the conventional wafer-level burn-in apparatus and FIG. 5(b) showing the temperature distribution in the vertical direction of the wafer when a thermal load is applied by the conventional wafer-level burn-in apparatus, the distribution of actual temperature on the wafer 101 increases toward the center when a thermal load at the set temperature of 125° C. is applied by the conventional wafer-level burn-in apparatus. Although temperature control is performed based on a temperature measured by the temperature sensor 109, the actual temperature deviates from 125° C.

The temperature difference is caused by the following two aspects:

First, in the case of the wafer holding tray 102 made of aluminum with a thermal conductivity of 200 W/m-K and a thickness of 10 mm, when the wafer 101 that is a conventional 8-inch wafer has heat of 400 W generated by the application of an electrical load, that is, when the wafer has a heat density of 12.74 kW/m², a temperature difference between both surfaces of the tray 102 is 0.6° C. On the other hand, in the case of a 300-mm wafer having a calorific value of 3 kW, that is, when the wafer has a heat density of 42.46 kW/m², a temperature difference between both surfaces of the tray 102 is 2.1° C.

In an actual configuration, a contact resistance occurs on the contact of the wafer 101 and the wafer holding tray 102 and the contact of the wafer holding tray 102 and the temperature sensor 109, in addition to the temperature difference between both surfaces of the tray. Since the resistance is proportionate to the heat density, the temperature difference further increases. In the case of a 300-mm wafer having a calorific value of 3 kW, a temperature difference between the wafer 101 and the temperature sensor 109 is about 6° C.

For this reason, it is difficult to guarantee a wafer temperature around 125° C. in the configuration of FIG. 4.

### DISCLOSURE OF THE INVENTION

In the conventional method, however, an electrical load is applied to a wafer that is a target of a burn-in test, by applying a predetermined voltage. At this point, a current applied to devices on the wafer varies among target wafers even when the wafer has devices of the same type. When it is assumed that a current of 1 is applied to a typical device, some devices are fed with a current of about 1.5. For this reason, even when devices are formed on wafers with the same yield rate, a calorific value may greatly vary among the wafers. Moreover, of devices formed on a wafer, an electrical load is not applied to devices judged as defective in upstream operations and thus heat is not generated by energization on the devices. For these reasons, in some cases, a difference occurs between a temperature measured by the temperature sensor and an actual temperature and thus a wafer temperature cannot be controlled to a desired temperature. Unfortunately, the wafer temperature increased by the temperature difference may cause considerable damage such as serious wear or burn on a probe for applying an electrical load to a wafer. Further, a temperature decrease may disadvantageously cause insufficient screening using a thermal load and defective devices may be introduced onto the market.

In order to solve the problems, an object of the present invention is to provide a wafer-level burn-in method and a wafer-level burn-in apparatus with high reliability which can prevent the wear and burn of a probe by controlling the temperature of a wafer to a desired temperature, not depending upon the distribution of good devices formed on the wafer and the power consumptions of devices.

In order to attain the object, a wafer-level burn-in method according to the present invention, in which one of an overall semiconductor wafer and a divided region of the semiconductor wafer is set as an area, and an electrical load and a thermal load are applied to devices on the semiconductor wafer to screen defective pieces, by means of a probe collectively making contact with all chips on the semiconductor wafer, the method including: applying the thermal load such that each area of the semiconductor wafer has a set temperature; applying the electrical load to the semiconductor wafer; determining a heat density on a good device of the semiconductor wafer based on power consumed on the semiconductor wafer by the application of the electrical load; calculating a correction value of each area based on the heat density; and correcting the set temperature according to the correction value and controlling the temperature of the thermal load in each area during the application of the electrical load.

Further, the power consumption is a design value.

Moreover, the power consumption is obtained by dividing an actually measured power consumption by the yield rate of the semiconductor wafer.

A wafer-level burn-in method according to the present invention, in which one of an overall semiconductor wafer and a divided region of the semiconductor wafer is set as an area, and an electrical load and a thermal load are applied to devices on the semiconductor wafer to screen defective pieces, by means of a probe collectively making contact with all chips on the semiconductor wafer, the method including: calculating a first correction value based on a first heat density on a good device of the semiconductor wafer, the heat density being obtained based on the design value of power consumed on the semiconductor wafer by the application of the electrical load; applying the thermal load to each area so as to have a set temperature corrected by the first correction value; applying the electrical load to the semiconductor wafer; measuring the power consumed on the semiconductor wafer by the electrical load; determining a second heat density on a good device of the semiconductor wafer by means of a value obtained by dividing the measured power consumption by the yield rate of the semiconductor wafer; calculating a second correction value based on the second heat density; and correcting the set temperature according to the second correction value and controlling the temperature of the thermal load in each area during the application of the electrical load.

Further, the heat density on a good device of the semiconductor wafer is obtained by averaging heat densities in the at least one area.

Moreover, the method further includes: setting a weight constant beforehand according to one of a distance from the sensor to each device on the semiconductor wafer and the number of devices between one of the devices and the sensor; and calculating the correction value as a function of the product of the sum of weight constants set for good devices and the heat density of each area.

Further, the correction value is calculated as a function of the heat density of each area.

Moreover, the set temperature is corrected after the application of the electrical load.

Further, the set temperature is corrected before the application of the electrical load.

A wafer-level burn-in apparatus according to the present invention, in which one of an overall semiconductor wafer and a divided region of the semiconductor wafer is set as an area, and an electrical load and a thermal load are applied to devices on the semiconductor wafer to screen defective pieces, by means of a probe collectively making contact with all chips on the semiconductor wafer, the apparatus including: a temperature sensor provided in each area to measure a semiconductor wafer temperature in each area; a heater provided in each area to heat the semiconductor wafer in each area; a cooling source provided in each area to cool the semiconductor wafer in each area; a temperature correction value calculator for calculating a temperature difference between the actual temperature of the semiconductor wafer in each area and a temperature measured by the temperature sensor in each area, as a correction value of each area based on a heat density on a good device of the semiconductor wafer; a temperature regulator for controlling heating of the heater and cooling of the cooling source such that the semiconductor wafer temperature measured by the temperature sensor in each area is equal to a temperature obtained by correcting a set temperature by the correction value; and a tester for inspecting the devices.

Further, the semiconductor wafer has a heat density obtained by averaging heat densities in the at least one area.

Moreover, the semiconductor wafer has a heat density determined by the design value of power consumption.

Further, the semiconductor wafer has a heat density obtained by dividing an actually measured power consumption by the yield rate of the semiconductor wafer.

Moreover, the apparatus has a weight constant set beforehand according to one of a distance from the sensor to each device on the semiconductor wafer and the number of devices between one of the devices and the sensor, and the correction value is calculated as a function of the product of the sum of weight constants set for good devices and the heat density of each area.

Further, the correction value is calculated as a function of the heat density of each area.

### BRIEF DESCRIPTION OF THE DRAWINGS

FIG. 1 is a schematic diagram showing a wafer-level burn-in apparatus according to a first embodiment of the present invention;

FIG. 2 is a schematic diagram showing a divided temperature regulating plate according to second and fourth embodiments of the present invention;

FIG. 3(a) is a schematic diagram showing weighting in area “a” according to the fourth embodiment of the present invention;

FIG. 3(b) is a schematic diagram showing weighting in area “b” according to a third embodiment of the present invention;

FIG. 3(c) is a schematic diagram showing weighting in area “c” according to the third embodiment of the present invention;

FIG. 3(d) is a schematic diagram showing weighting in area “d” according to the third embodiment of the present invention;

FIG. 3(e) is a schematic diagram showing weighting in area “e” according to the third embodiment of the present invention;

FIG. 4 is a schematic diagram showing a conventional wafer-level burn-in apparatus;

FIG. 5(a) is a temperature distribution in the horizontal direction of a wafer when a thermal load is applied by the conventional wafer-level burn-in apparatus;

FIG. 5(b) is a temperature distribution in the vertical direction of the wafer when a thermal load is applied by the conventional wafer-level burn-in apparatus;

FIG. 6 is a schematic diagram showing a wafer-level burn-in apparatus according to the second and fourth embodiments of the present invention; and

FIG. 7 is a schematic diagram showing weighting according to the third embodiment of the present invention.

### BEST MODE FOR CARRYING OUT THE INVENTION

The following will describe embodiments of the present invention in accordance with the accompanying drawings.

### First Embodiment

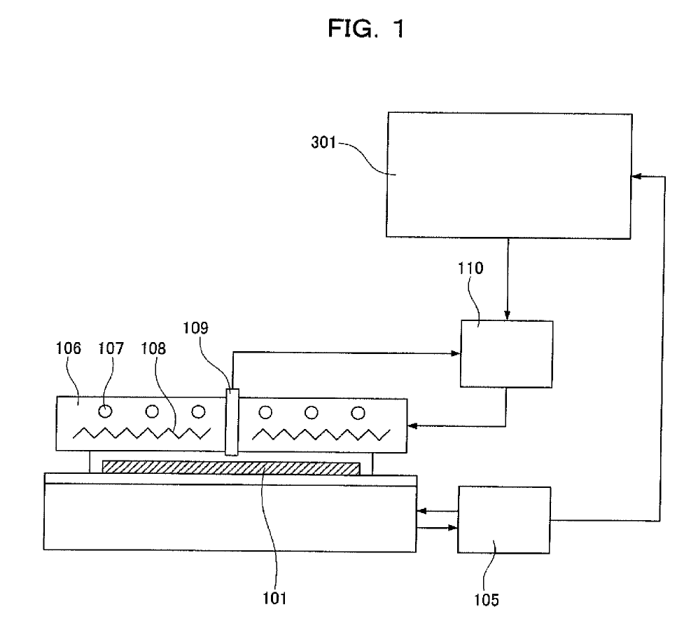

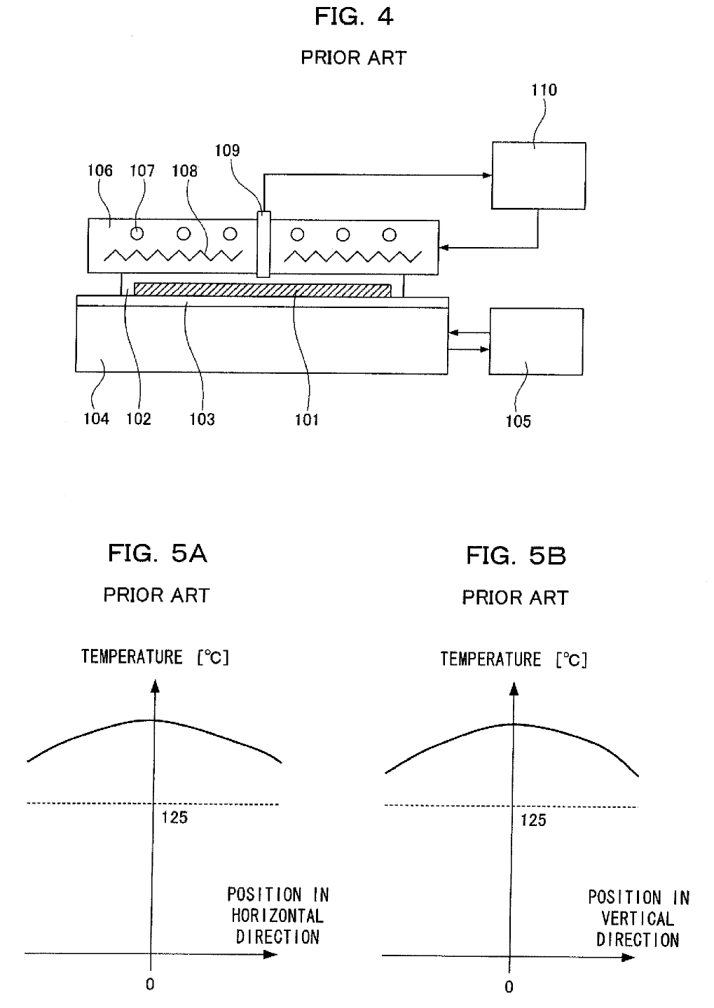

FIG. 1 is a schematic diagram showing a wafer-level burn-in apparatus according to a first embodiment of the present invention. In the first embodiment of FIG. 1, a temperature correction value calculator 301 is added to the configuration of FIG. 4.

In wafer-level burn-in using this configuration according to the first embodiment, when an electrical load is applied to devices formed on a wafer 101, a difference between the actual temperature of the wafer 101 heated by the power consumption of the devices and a temperature measured by a temperature sensor 109 is calculated beforehand by experiment as a calorific value per unit area of the wafer 101, that is, a heat density function. The first embodiment uses the following direct proportional relationship:

ΔT=γ×D (1)

where ΔT represents a difference between the actual temperature of the wafer 101 and a temperature measured by the temperature sensor 109, D represents the heat density of good devices on the wafer 101, and γ represents the coefficient of a difference between the actual temperature of the wafer 101 and a temperature measured by the temperature sensor 109 and a heat density on the wafer 101. The coefficient is derived from the relationship between the temperature sensor 109 and a wafer temperature at each heat density through experiment in which the temperature sensor is installed beforehand and a wafer allowing heat generation at a desired heat density is used. In the temperature correction value calculator 301, electrical continuity test results on devices formed on the wafer 101 in upstream operations are obtained beforehand, regarding each wafer on which wafer-level burn-in is performed. And then, temperature control is performed using a temperature obtained by correcting the measurement value of the temperature sensor 109 by a correction value.

To be specific, during the burn-in of the wafer, the wafer is heated from room temperature to 125° C. by heaters 108 and is stabilized at 125° C. And then, an electrical load is applied to devices on the wafer from a tester 105. Immediately after the electrical load is applied, the current of the electrical load applied by the tester 105 is measured and power consumed on the wafer 101 by the electrical load is calculated based on an applied voltage. The calculated value of power consumption is transmitted to the temperature correction value calculator 301. This value is divided by a yield rate obtained by the continuity test results on the devices formed on the wafer 101, so that the power consumption of the devices formed on the wafer 101 at a yield rate of 100% is obtained. The power consumption obtained at the yield rate of 100% is divided by the area of the wafer 101, so that an average heat density of the overall wafer 101 is calculated. The reason why the power consumption at the yield rate of 100% is used is that heat generated on the wafer 101 passes through a tray 102 and is dissipated from a temperature regulating plate and the magnitude of a heat flux at that time determines a temperature gradient from the wafer 101 to the temperature sensor 109 and a temperature difference between the wafer 101 and the temperature sensor 109. Another reason is that by using the power consumption when the yield rate of the devices is 100%, the temperature gradient from the wafer 101 to the temperature sensor 109 and the maximum temperature difference are calculated and the temperature is corrected to prevent the wafer 101 and a probe 103 from being heated to a set temperature or higher. By using formula (1) based on the obtained heat density, ΔT is calculated and a signal is transmitted from the temperature correction value calculator 301 to a temperature regulator 110 so as to have a temperature set value of (125−ΔT)° C., so that the temperature measured by the temperature sensor 109 is controlled to (125−ΔT)° C. Thus the wafer 101 is controlled to 125° C.

In the first embodiment, the correction value is derived by determining the power consumption of the wafer 101 during the application of an electrical load. In the case of a small deviation from the design value of power consumption of the wafer 101, the correction value may be derived based on the design value of power consumption. Further, as a first correction value, a correction value calculated based on the design value of power consumption may be used until an electrical load is applied, and a second correction value may be calculated based on the power consumption of the wafer 101 after the electrical load is applied. The power consumption of the wafer 101 is determined by measuring a current of the wafer. Although a coolant is used as a cooling source, wind generated by a blower such as a fan may be blown to the temperature regulating plate. In this case, the temperature regulating plate including a fin improves cooling capability. Although the burn-in temperature is set at 125° C., a different temperature may be set under some conditions. As expressed in formula (1), a difference between the temperature of the wafer 101 heated by the power consumption of the devices and a temperature measured by the temperature sensor 109 is directly proportionate to the heat density of the wafer 101. Under some conditions of the apparatus, other relations, e.g., a constant term included in formula (1) may be established.

As described above, during the measurement of a temperature by the temperature sensor, the temperature is corrected using the derived heat density function of the wafer, thereby eliminating an offset of the measured temperature, the offset being caused by a temperature difference between a surface of the wafer and the top surface of the tray. Thus it is possible to provide a wafer-level burn-in method and a wafer-level burn-in apparatus with high reliability which can accurately control a temperature and prevent the wear and burn of a probe.

### Second Embodiment

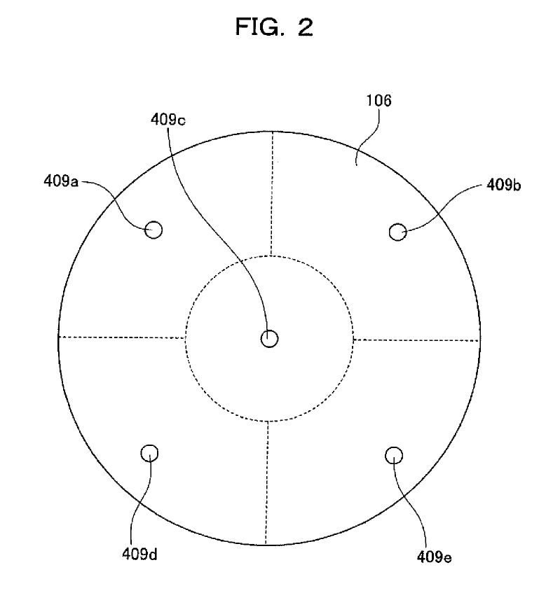

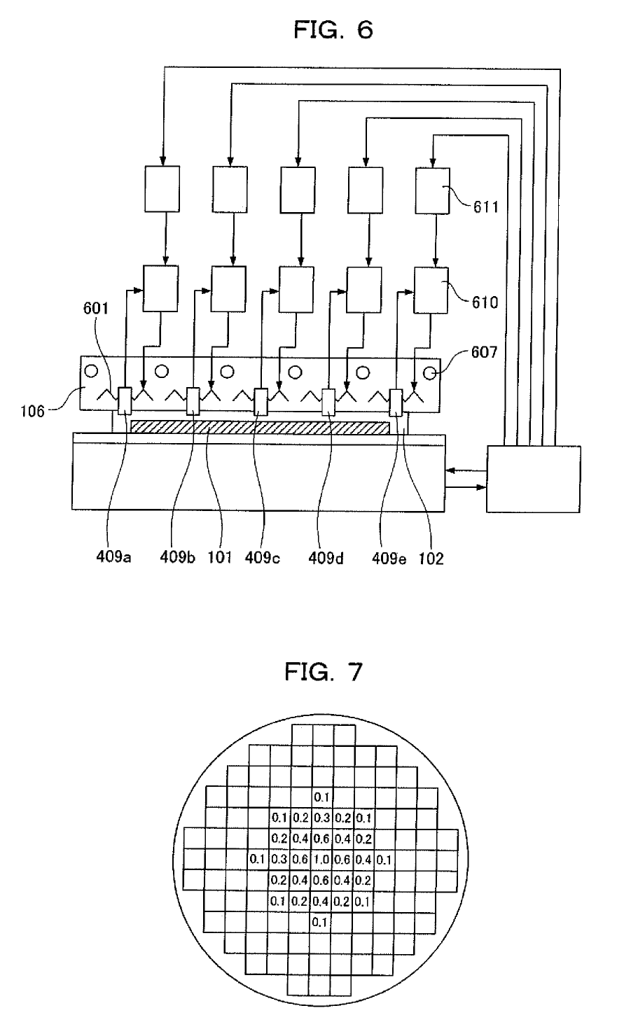

FIG. 2 is a schematic diagram showing a divided temperature regulating plate according to a second embodiment of the present invention. FIG. 6 is a schematic diagram showing a wafer-level burn-in apparatus according to the second embodiment.

In the second embodiment of the present invention, as shown in FIG. 2, a temperature regulating plate 106 in the configuration of FIG. 1 is divided into five areas of area “a” to “e”. As shown in FIG. 6, heaters 601, coolant passages 607, temperature sensors 409a to 409e, temperature regulators 610, and temperature correction value calculators 611 are independently disposed and temperature control is performed for each divided area. In other words, unlike the first embodiment for handling a measurement error caused by a heat density, the second embodiment also handles variations in heat density in the respective areas of a wafer.

In wafer-level burn-in according to the second embodiment configured thus, when an electrical load is applied to devices formed on a wafer 101, differences between actual temperatures in the respective areas of the wafer 101 heated by the power consumption of the devices and temperatures measured by the temperature sensors 409a to 409e are calculated beforehand by experiment as calorific values per unit areas in the respective areas of the wafer 101, that is, functions of heat density. In the second embodiment, the following direct proportional relationships are used:

ΔTa=γa×Da (2-a)

ΔTb=γb×Db (2-b)

ΔTc=γc×Dc (2-c)

ΔTd=γd×Dd (2-d)

ΔTe=γe×De (2-e)

where ΔT represents differences between actual temperatures in the respective areas of the wafer 101 and temperatures measured by the temperature sensors 409a to 409e, Da to De represent the heat densities of good devices in the respective areas of the wafer 101, and γa to γe represent the coefficients of differences between the actual temperatures in the respective areas of the wafer 101 and temperatures measured by the temperature sensors 409a to 409e and heat densities in the respective areas of the wafer 101. The coefficients are derived from the relationships between the temperature sensors 409a to 409e and water temperatures at each heat density through experiment in which the temperature sensors are installed beforehand and a wafer allowing heat generation at a desired heat density is used. In the temperature correction value calculators 611, electrical continuity test results on the respective areas of devices formed on the wafer 101 in upstream operations are obtained beforehand, regarding each wafer on which wafer-level burn-in is performed. And then, temperature control is performed using temperatures obtained by correcting the measurement values of the temperature sensors 409a to 409e by correction values.

To be specific, during the burn-in of the wafer, the wafer is heated from room temperature to 125° C. by heaters 608 and is stabilized at 125° C. And then, an electrical load is applied from a tester 105 to the devices on the wafer. Immediately after the electrical load is applied, the current of the electrical load applied by the tester 105 is measured and powers consumed in the respective areas of the wafer 101 by the electrical load are calculated based on an applied voltage. The calculated values of power consumption are transmitted to the temperature correction value calculators 611. These values are divided by a yield rate obtained by continuity test results on the devices formed in the respective areas of the wafer 101, so that the power consumptions of the devices formed in the respective areas of the wafer 101 are obtained with a yield rate of 100%. The power consumptions obtained with a yield rate of 100% are divided by the areas of the respective areas of the wafer 101, so that average heat densities in the respective areas of the wafer 101 are calculated. The reason why the power consumptions with the yield rate of 100% are used is that when heat generated on the wafer 101 passes through a tray 102 and is dissipated from the temperature regulating plate, the magnitude of a heat flux determines a temperature gradient from the wafer 101 to the temperature sensors 409a to 409e and determines a temperature difference. Another reason is that by using the power consumptions when the yield rate of the devices is 100%, the temperature gradient from the wafer 101 to the temperature sensors 409a to 409e and the maximum temperature difference are calculated and the temperatures are corrected to prevent the wafer 101 and a probe 103 from being heated to a set temperature or higher. By using formulas (2-a) to (2-e) based on the obtained heat densities, ΔTa to ΔTe are calculated and signals are transmitted from the temperature correction value calculators 611 to the temperature regulators 610 so as to have temperature set values of (125−ΔTa)° C. to (125−ΔTe)° C., so that temperatures measured by the temperature sensors 409a to 409e are controlled to (125−ΔTa)° C. to (125−ΔTe)° C. Thus the respective areas of the wafer 101 are controlled to 125° C.

In the second embodiment, the correction values are derived by determining power consumptions in the respective areas of the wafer 101 during the application of an electrical load. In the case of a small deviation from the design values of power consumptions for the respective areas of the wafer 101, the correction values may be derived based on the design values of power consumptions. Further, a correction value calculated based on the design value of power consumption may be used as a first correction value until an electrical load is applied, and a second correction value may be calculated based on the power consumptions of the respective areas of the wafer 101 after the electrical load is applied. The power consumptions are determined by measuring currents. Although a coolant is used as a cooling source, wind generated by a blower such as a fan may be blown to the temperature regulating plate. In this case, the temperature regulating plate including a fin improves cooling capability. Although the burn-in temperature is set at 125° C., a different temperature may be set under some burn-in conditions. As expressed in formula (1), differences between temperatures in the respective areas of the wafer 101 heated by the power consumption of the devices and temperatures measured by the temperature sensors 409a to 409e are directly proportionate to the heat densities of the respective areas of the wafer 101. Under some conditions of the apparatus, other relations, e.g., a constant term included in formula (1) may be established. Moreover, in the second embodiment, power consumptions are determined in the respective areas. As in the first embodiment, a correction value may be calculated by determining the power consumption of the overall wafer 101 and temperature control may be performed in each of the areas.

Although the area is divided into five in the present embodiment, the area may be divided into any number of areas. In the first embodiment, the number of divided areas is 1 and the area is equivalent to the overall wafer.

As described above, during the measurement of temperatures by the temperature sensors, the temperatures are corrected using the derived heat density functions of the wafer, thereby eliminating offsets of the measured temperatures, the offsets being caused by a temperature difference between a surface of the wafer and the top surface of the tray. Thus it is possible to provide a wafer-level burn-in method and a water-level burn-in apparatus with high reliability which can accurately control a temperature and prevent the wear and burn of a probe.

### Third Embodiment

A third embodiment of the present invention is configured like the first embodiment of FIG. 1.

In wafer-level burn-in according to the third embodiment, regarding a difference between a temperature measured by a temperature sensor 109 and the actual temperature of a wafer 101 during heat generation on devices by power consumption, the influence varies with a distance between the temperature sensor 109 and the devices formed on the wafer 101. Considering this point, a weight constant is set for each device according to a distance in the planar direction of the wafer 101 from the temperature sensor 109 based on the relationship between the temperatures of the temperature sensor 109 and the wafer 101 in each thermal distribution and at each heat density, through experiment in which the temperature sensor is installed beforehand and a wafer allowing heat generation with a desired thermal distribution and a desired heat density is used. In other words, unlike the first embodiment for handling a measurement error caused by a heat density, the third embodiment also handles an error caused by variations in the distribution of good devices near the temperature sensor.

In the third embodiment, a weight constant is set by the function below:

α=e^{-kr} (3)

where α represents a weight constant, r represents a distance in the planar direction of the wafer 101 from the temperature sensor 109, and k represents a coefficient. The smaller the coefficient, the greater the influence of heat generated on devices far from the temperature sensor 109. FIG. 7 is a schematic diagram showing weighting according to the third embodiment of the present invention. As shown in FIG. 7, each device is weighted according to formula (3).

Further, in a temperature correction value calculator 301, electrical continuity test results on devices formed on the wafer 101 in upstream operations are obtained, regarding each wafer on which wafer-level burn-in is performed. α of each good device is calculated using formula (3), the sum of α set for the good devices is determined, and a difference between the temperature of the wafer 101 and a temperature measured by the temperature sensor 109 is determined by formula (4):

ΔT=(the sum of α set for good devices)×Hr (4)

where ΔT represents a difference between the actual temperature of the wafer 101 and a temperature measured by the temperature sensor 109 and Hr represents a coefficient proportionate to the heat density of the wafer 101. The coefficient is calculated by dividing a difference between the actual temperature of the wafer 101 and a temperature measured by the temperature sensor 109 by the sum of α set for good devices when devices are formed on the wafer 101 for burn-in with a yield rate of 100%. α, k and Hr in formulas (3) and (4) are set according to the devices formed on the wafer 101 and the burn-in conditions.

In actual burn-in of the wafer, the wafer is heated from room temperature to 125° C. by heaters 108 and is stabilized at 125° C. And then, an electrical load is applied from a tester 105 to the devices on the wafer. At the same time, a signal is transmitted from the temperature correction value calculator 301 to a temperature regulator 110 so as to have a temperature set value of (125−ΔT)° C., and a temperature measured by the temperature sensor 109 is controlled to (125−ΔT)° C. Thus the wafer 101 is controlled to 125° C.

In the third embodiment, r in formula (3) is a distance in the planar direction of the wafer 101 from the temperature sensor 109. r may be a direct distance from the temperature sensor 109 to a target device on the wafer 101. Thus an error of a distance from the temperature sensor 109 to the wafer 101 decreases. Further, in the third embodiment, the method of setting a weight constant is the function of a distance from the temperature sensor. The weight constant may be set by the number of devices from the reference device closest to the sensor. In the third embodiment, a correction value is derived by determining the power consumption of the wafer 101 during the application of an electrical load. In the case of a small deviation from the design value of power consumption of the wafer 101, a correction value may be derived based on the design value of power consumption. Further, as a first correction value, a correction value calculated based on the design value of power consumption may be used until an electrical load is applied, and a second correction value may be calculated based on the power consumption of the wafer 101 after the electrical load is applied. The power consumption of the wafer 101 is determined by measuring a current. Although a coolant is used as a cooling source, wind generated by a blower such as a fan may be blown to the temperature regulating plate. In this case, the temperature regulating plate including a fin improves cooling capability. Although the burn-in temperature is set at 125° C., a different temperature may be set under some burn-in conditions. Moreover, although the temperature is corrected after the application of an electrical load, the temperature may be corrected when the wafer is heated from room temperature. Regarding formulas (3) and (4), other relations may be established under some conditions of the apparatus.

As described above, during the measurement of a temperature by the temperature sensor, the temperature is corrected by determining the function of a distance from the temperature sensor to a good device and using the sum of all good devices according to the function, thereby suppressing a deviation of a temperature correction value, the deviation being caused by variations in the distribution of good devices near the temperature sensor. Thus it is possible to provide a wafer-level burn-in method and a wafer-level burn-in apparatus with high reliability which can accurately control a temperature and prevent the wear and burn of a probe.

### Fourth Embodiment

A fourth embodiment of the present invention is configured like the second embodiment of FIG. 6.

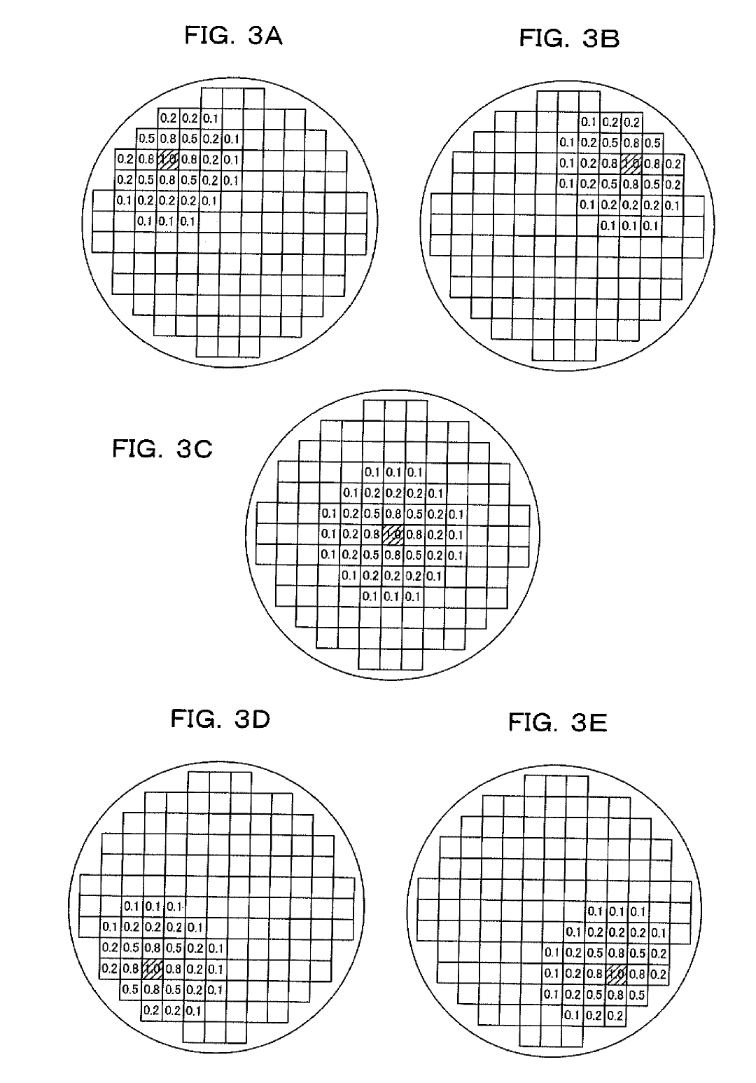

In wafer-level burn-in according to the fourth embodiment configured thus, regarding differences between temperatures measured by temperature sensors 409a to 409e and the actual temperature of a wafer 101 during heat generation on devices by power consumption, the influence varies in each area with distances between the temperature sensors 409a to 409e and devices formed on the wafer 101. Considering this point, a weight constant is set for each device according to a distance in the planar direction of the wafer 101 from the temperature sensors 409a to 409e based on the relationship between the temperatures of the temperature sensors 409a to 409e and the wafer 101 in each thermal distribution and at each heat density, through experiment in which the temperature sensors are installed beforehand and the wafer allowing heat generation with a desired thermal distribution and a desired heat density is used. In other words, in addition to an error caused by variations in the distribution of good devices near the temperature sensor in the third embodiment, the fourth embodiment also handles variations in heat density in the areas of a wafer. FIG. 3(a) is a schematic diagram showing weighting in area “a” according to the fourth embodiment of the present invention. FIG. 3(b) is a schematic diagram showing weighting in area “b” according to the fourth embodiment of the present invention. FIG. 3(c) is a schematic diagram showing weighting in area “c” according to the fourth embodiment of the present invention. FIG. 3(d) is a schematic diagram showing weighting in area “d” according to the fourth embodiment of the present invention. FIG. 3(e) is a schematic diagram showing weighting in area “e” according to the fourth embodiment of the present invention. As shown in FIGS. 3(a) to 3(e), relative to devices (diagonally shaded in FIG. 3) each having the temperature sensor disposed in a position orthogonal to a wafer surface and provided for controlling the temperature of the thermal load, weight constants αa to αe monotonously decreasing with the number of devices from the reference device are set for the temperature sensors 409a to 409e, respectively. With this method, the weight constants can be set only by designating the reference device, regardless of the sizes of devices.

Further, in temperature correction value calculators 611, electrical continuity test results on the devices formed on the wafer 101 in upstream operations are obtained, regarding each wafer on which wafer-level burn-in is performed. The sum of α set for good devices is determined and differences ΔTa to ΔTe between the actual temperature of the wafer 101 and temperatures measured by the temperature sensors 409a to 409e are determined by formulas 5(a) to 5(e) below:

ΔTa=(the sum of αa set for good devices)×Hna (5a)

ΔTb=(the sum of αb set for good devices)×Hnb (5b)

ΔTc=(the sum of αc set for good devices)×Hnc (5c)

ΔTd=(the sum of αd set for good devices)×Hnd (5d)

ΔTe=(the sum of αe set for good devices)×Hne (5e)

where ΔTa to ΔTe represent differences between the actual temperature of the wafer 101 and temperatures measured by the temperature sensors 409a to 409e and Hna to Hne represent coefficients proportionate to the heat density of the wafer 101. The coefficients are calculated by dividing differences between the actual temperature of the wafer 101 and temperatures measured by the temperature sensors 409a to 409e by the respective sums of αa to αe set for good devices when devices are formed on the wafer 101 for burn-in with a yield rate of 100%. In formulas (5a) and (5e), αa to αe and Hna to Hne are set according to the devices formed on the wafer 101 and the burn-in conditions.

In actual burn-in of the wafer, the wafer is heated from room temperature by the heaters of the respective areas. Signals are transmitted from the temperature correction value calculators 611 to temperature regulators 610 so as to have temperature set values of (125−ΔTa)° C. to (125−ΔTe)° C. by using ΔTa to ΔTe calculated by formulas (5a) to (5e) with Hna to Hne determined based on a design value of power consumption, and temperatures measured by the temperature sensors in the respective areas are controlled to (125−ΔTa)° C. to (125−ΔTe)° C. After stabilized at (125−ΔTa)° C. to (125−ΔTe)° C., an electrical load is applied from a tester 105 to the devices formed on the wafer. Immediately after the application of the electrical load, the current of the electrical load applied from the tester 105 is measured and power consumed on the wafer 101 by the electrical load is calculated based on an applied voltage. The calculated value of power consumption is transmitted to the temperature correction value calculators 611. This value is divided by a yield rate obtained by continuity test results on the devices formed on the wafer 101, so that the power consumption of the devices formed on the wafer 101 at a yield rate of 100% is obtained. The heat density of the wafer 101 is calculated based on the obtained power consumption. Since Hda to Hde are proportionate to the heat density of the wafer 101, the values of Hda to Hde are corrected, ΔTa to ΔTe are calculated again using formulas (5a) to (5e), and signals are transmitted from the temperature correction value calculators 611 to the temperature regulators 610 so as to have temperature set values of (125−ΔTa)° C. to (125−ΔTe)° C. in the respective areas. Thus it is possible to correct a deviation of power consumption from a device design value, the deviation being caused by variations in processing during the formation of devices. Thus the wafer 101 can be controlled to 125° C. with higher accuracy. In the fourth embodiment, as a first correction value, a correction value calculated based on the design value of power consumption is used until an electrical load is applied and a second correction value is calculated based on the power consumptions of the respective areas of the wafer 101 after the electrical load is applied. The power consumptions are determined by measuring currents. In the case of a small deviation from the design values of power consumption of the respective areas of the wafer 101, the temperature may be corrected only based on the design values of power consumption or only by determining the power consumptions of the respective areas of the wafer 101 during the application of the electrical load. Moreover, in the second embodiment, power consumption is determined in each area. As in the third embodiment, a correction value may be calculated by determining power consumption over the wafer 101.

Although a coolant is used as a cooling source in the fourth embodiment, wind generated by a fan may be blown to a temperature regulating plate. In this case, the temperature regulating plate including a fin improves cooling capability. Although the burn-in temperature is set at 125° C., a different temperature may be set under some burn-in conditions. Moreover, although the temperature is corrected after the application of an electrical load, the temperature may be corrected when the wafer is heated from room temperature. Regarding formulas (5a) to (5e), other relations may be established under some conditions of the apparatus.

Although the area is divided in five in the present embodiment, the area may be divided into any number of areas. In the third embodiment, the number of divided areas is 1 and the area is equivalent to the overall wafer.

As described above, the temperature regulating plate is divided into a plurality of areas each of which includes the temperature sensor, the heater, and a coolant passage During the measurement of temperatures by the temperature sensors, the temperatures are corrected in the respective areas by determining the functions of distances from the temperature sensors to good devices and using the sums of good devices in the respective areas according to the functions, and temperature control is performed for each area, so that the temperature control can be accurately performed. Thus it is possible to provide a wafer-level burn-in method and a wafer-level burn-in apparatus with high reliability which can prevent the wear and burn of a probe.

1. A wafer-level burn-in method, in which one of an overall semiconductor wafer and a divided region of the semiconductor wafer is set as an area, and an electrical load and a thermal load are applied to devices on the semiconductor wafer to screen a defective piece, by means of a probe collectively making contact with all chips on the semiconductor wafer,
the method comprising:
applying the thermal load such that each area of the semiconductor wafer has a set temperature;
applying the electrical load to the semiconductor wafer;
determining a heat density on a good device of the semiconductor wafer based on power consumed on the semiconductor wafer by application of the electrical load;
calculating a correction value of each area based on the heat density; and
correcting the set temperature by the correction value and controlling a temperature of the thermal load in each area during the application of the electrical load.

2. The wafer-level burn-in method according to claim 1, wherein the power consumption is a design value.

3. The wafer-level burn-in method according to claim 1, wherein the power consumption is obtained by dividing an actually measured power consumption by a yield rate of the semiconductor wafer.

4. A wafer-level burn-in method, in which one of an overall semiconductor wafer and a divided region of the semiconductor wafer is set as an area, and an electrical load and a thermal load are applied to devices on the semiconductor wafer to screen a defective piece, by means of a probe collectively making contact with all chips on the semiconductor wafer,
the method comprising:
calculating a first correction value based on a first heat density on a good device of the semiconductor wafer, the heat density being obtained based on a design value of power consumed on the semiconductor wafer by application of the electrical load;
applying the thermal load to each area so as to have a set temperature corrected by the first correction value;
applying the electrical load to the semiconductor wafer;
measuring the power consumed on the semiconductor wafer by the electrical load;
determining a second heat density on a good device of the semiconductor wafer by means of a value obtained by dividing the measured power consumption by a yield rate of the semiconductor wafer;
calculating a second correction value based on the second heat density; and
correcting the set temperature by the second correction value and controlling a temperature of the thermal load in each area during the application of the electrical load.

5. The wafer-level burn-in method according to claim 1, wherein the heat density on a good device of the semiconductor wafer is obtained by averaging heat densities in the at least one area.

6. The wafer-level burn-in method according to claim 1, further comprising:
setting a weight constant beforehand according to one of a distance from the sensor to each device on the semiconductor wafer and the number of devices between one of the devices and the sensor; and
calculating the correction value as a function of a product of a sum of weight constants set for good devices and the heat density of each area.

7. The wafer-level burn-in method according to claim 1, wherein the correction value is calculated as a function of the heat density of each area.

8. The wafer-level burn-in method according to claim 1, wherein the set temperature is corrected after the application of the electrical load.

9. The wafer-level burn-in method according to claim 1, wherein the set temperature is corrected before the application of the electrical load.

10. A wafer-level burn-in apparatus, in which one of an overall semiconductor wafer and a divided region of the semiconductor wafer is set as an area, and an electrical load and a thermal load are applied to devices on the semiconductor wafer to screen a defective piece, by means of a probe collectively making contact with all chips on the semiconductor wafer,
the apparatus comprising:
a temperature sensor provided in each area to measure a semiconductor wafer temperature in each area;
a heater provided in each area to heat the semiconductor wafer in each area;
a cooling source provided in each area to cool the semiconductor wafer in each area;
a temperature correction value calculator for calculating a temperature difference between an actual temperature of the semiconductor wafer in each area and a temperature measured by the temperature sensor in each area, as a correction value of each area based on a heat density on a good device of the semiconductor wafer;
a temperature regulator for controlling heating of the heater and cooling of the cooling source such that the semiconductor wafer temperature measured by the temperature sensor in each area is equal to a temperature obtained by correcting a set temperature by the correction value; and
a tester for inspecting the devices.

11. The wafer-level burn-in apparatus according to claim 10, wherein the semiconductor wafer has a heat density obtained by averaging heat densities in the at least one area.

12. The wafer-level burn-in apparatus according to claim 10, wherein the semiconductor wafer has a heat density determined by a design value of power consumption.

13. The wafer-level burn-in apparatus according to claim 10, wherein, the semiconductor wafer has a heat density obtained by dividing an actually measured power consumption by a yield rate of the semiconductor wafer.

14. The wafer-level burn-in apparatus according to claim 10, wherein, the apparatus has a weight constant set beforehand according to one of a distance from the sensor to each device on the semiconductor wafer and the number of devices between one of the devices and the sensor, and
the correction value is calculated as a function of a product of a sum of weight constants set for good devices and the heat density of each area.

15. The wafer-level burn-in apparatus according to claim 10, wherein, the correction value is calculated as a function of a heat density of each area.
